(19) United States
(12) Patent Application Publication
(10) Pub. No.: US 2006/0094225 A1
(43) Pub. Date: May 4, 2006

(54) Methods for forming solder bumps on circuit boards

(76) Inventors: Cheng-Yuan Lin, Taoyuan Hsien (TW); Te-Chang Huang, Taoyuan Hsien (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/974,883

(22) Filed: Oct. 28, 2004

(51) Int. Cl. H01L 21/44

(52) U.S. Cl. 438/613

(57) ABSTRACT

This invention relates to a method for forming solder bumps on a circuit board, which is formed with a solder resist and pads thereon and the pads are exposed from the solder resist. The steps of the method mainly are: Firstly, strengthen the solder resist by ultraviolet rays and then rough the solder resist by plasma treatments. Next, lay over a photosensitive dry film onto the solder resist and form openings on the photosensitive dry film for exposing the correspondent pads by exposure and development treatments. Last, form spherical solder bumps on the pads within the openings and remove the photosensitive dry film.

### FIELD OF THE INVENTION

The present invention generally relates to a method for forming solder bumps on a circuit board, and more particularly, relates to a method for forming fine pitch solder bumps on circuit board pads.

### BACKGROUND OF THE INVENTION

In surface mounting technology, circuit board pads exposed from solder resists are provided for soldering with surface mount devices, such as ball grid array (BGA), quad flat package (QFP) and so on. In general, the circuit board pads are precoated with solder for improving solder fusion and self-alignment effect, while bumps of the BGA or flip chips are soldered with the circuit board pads. Therefore, a solder precoating procedure is considered as an essential procedure for the surface mounting technology.

A conventional solder precoating method for forming solder bumps on pads is the stencil printing method and the steps of the methods are: Firstly, form hollowed out patterns to a stainless steel stencil and the patterns are designed for corresponding to pads formed on a circuit board. Then, cover the circuit board with the stainless steel stencil, and align the circuit board and the stainless steel stencil for exposing the pads from the patterns. Next, use a squeegee to fill the patterns with solder paste and then remove the stainless steel stencil. And apply reflow treatments to the circuit board for forming solder bumps.

However, for minifying sizes of the surface mount devices and achieving of ultra fine pitches demands in the surface mounting technology, the conventional stencil printing method is hard to achieve such demands, because it is difficult to hollow out ultra fine pitch patterns, such as 0.15 mm below pitches, to the stainless steel stencil. Although, the patterns can be somehow formed to the stainless steel stencil, it generally results in poor registration while applying to the circuit board and that makes the pads exposed from the patterns incompletely. In addition, the use of the stainless steel stencil easily fails in filling the patterns with the solder paste, namely to fail in controlling the quantity of the solder paste due to the difficulty in pattern formation and the poor registration between the stainless steel stencil and the circuit board.

### SUMMARY OF THE INVENTION

The present invention mainly provides a method for forming solder bumps on a circuit board that not only achieves the ultra fine pitch demands in surface mounting but also improves on controlling the quantity of the solder paste in filling solder paste procedure.

More specifically, the circuit board of the present invention is formed with a solder resist and pads thereon and the pads are exposed from the solder resist. The method comprises the steps of: Strengthen the solder resist by ultraviolet rays first and then rough the solder resist by plasma treatments. Next, lay over a photosensitive dry film onto the solder resist and form openings on the photosensitive dry film by exposure and development treatments for exposing the correspondent pads. Last, form spherical solder bumps on the pads within the openings by filling and reflow treatments, and then remove the photosensitive dry film.

The steps of strengthening the solder resist and roughing the solder resist are essential for the present invention, because the strengthened solder resist prevents destruction from the exposure and development treatments and the roughed solder resist helps the photosensitive dry film steadily attached to the solder resist. Furthermore, applying the exposure and development treatments to the photosensitive dry film can easily form the ultra fine pitch patterns. Besides, applying the photosensitive dry film to instead of the use of the stainless steel stencil prevents the poor registration and the failure in filling the paste solder because the patterns corresponded to the pads are formed after laying over the photosensitive dry film onto the solder resist that saves from the conventional alignment requirements.

### BRIEF DESCRIPTION OF THE DRAWINGS

The invention will be more clearly understood after referring to the following detailed description read in conjunction with the drawings wherein:

FIG. 1 is a cross sectional view of part of a circuit board as one embodiment of the present invention, illustrating a step of strengthening a solder resist of the circuit board by ultraviolet rays;

FIG. 2 illustrates a subsequent step to FIG. 1, showing the solder resist being roughed by plasma treatments;

FIG. 3 illustrates a subsequent step to FIG. 2, showing a photosensitive dry laid over the solder resist;

FIG. 4 illustrates a subsequent step to FIG. 3, showing the photosensitive dry film being formed with openings for exposing circuit board pads;

FIG. 5 illustrates a subsequent step to FIG. 4, showing filling the openings of the photosensitive dry film with solder;

FIG. 6 illustrates a subsequent step to FIG. 5, showing the solder being formed into spherical solder bumps; and

FIG. 7 illustrates a subsequent step to FIG. 6, showing the photosensitive dry film being removed.

### DETAILED DESCRIPTION OF THE PREFERRED EMBODIMENT

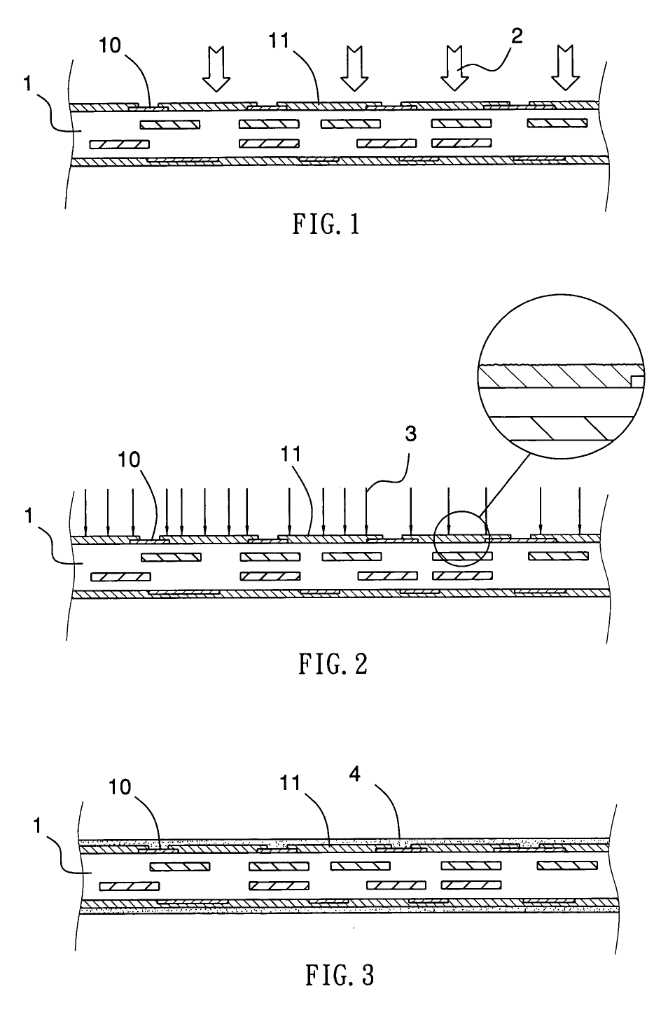

FIGS. 1-7 show an embodiment of the present invention and the sequential steps of a method for forming solder bumps on a circuit board. In FIG. 1, the circuit board 1 of the embodiment is a multilayer circuit board with conductor patterns and is formed with a solder resist 11 and pads 10 thereon; furthermore, the pads 10 are exposed from the solder resist 11. The steps of the method are: Firstly, strengthen the solder resist 11. The solder resist 11 is strengthened by applying ultraviolet rays 2 to irradiate the solder resist 11 and the radiation of the ultraviolet rays 2 is set between 400-1500 J/mm².

Next, rough the solder resist 11 by applying plasma treatments 3 to the surface of the solder resist 1 in order to form a rough surface on the solder resist 11, as shown in FIG. 2. Then, lay over a photosensitive dry film 4 onto the solder resist 11, referring to FIG. 3. The photosensitive dry film 4 is therefore steadily attached to the solder resist 11, due to the previously rough step.

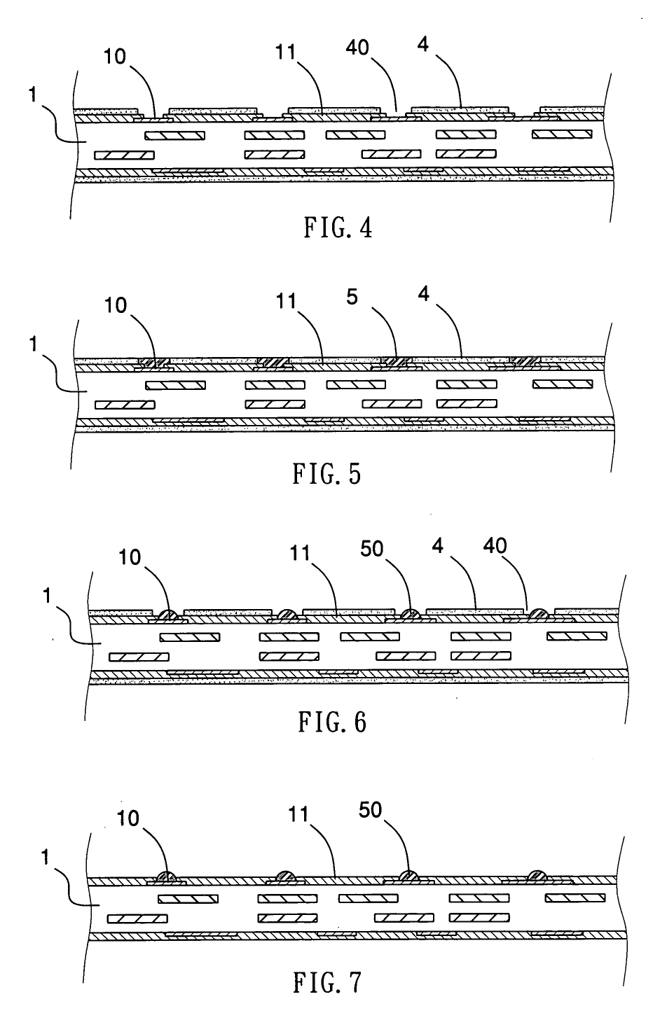

In FIG. 4, the sequential step is to form openings 40 on the photosensitive dry film 4 by exposure and development treatments for exposing the correspondent pads 10. Then, bake the photosensitive dry film 4 by a temperature of 120° C. for enhancing the strength and stability of the photosensitive dry film 4 to the solder resist 11.

Last, FIGS. 5-7 show the steps of forming solder bumps on the pads 10. In FIG. 5, the openings 40 are filled with solder 5, such solder paste. Next, apply reflow treatments to the solder 5 for forming spherical solder bumps 50 on the pads 10 within the openings 40, referring to FIG. 6. Then, remove the photosensitive dry film 4 and the solder bumps 50 are ready for soldering with surface mount devices, as shown in FIG. 7.

According to the embodiment of the present invention, the photosensitive dry film 4 has replaced the conventional stainless steel stencil for forming the ultra fine pitch patterns, namely the openings 40, and the solder bumps 50 on the pads 10 within the openings 40, due to the strengthened and roughed solder resist 11. In addition, the photosensitive dry film 4 is easy to form the ultra fine pitches than the conventional stainless steel stencil by applying the exposure and development treatments to the photosensitive dry film 4. Therefore, by strengthening and roughing the solder resist and applying the photosensitive dry film, the present invention prevents the conventional poor registration and the failure in filling the paste solder for the surface mounting demands.

Numerous characteristics and advantages of the invention have been set forth in the foregoing description, together with details of the structure and function of the invention, and the novel features thereof are pointed out in appended claims. The disclosure, however, is illustrated only, and changes may be made in detail, especially, in matters of shape, size and arrangement of parts, materials and the combination thereof within the principle of the invention, to the full extent indicated by the broad general meaning of the terms in which the appended claims are expressed.

We claim:

1. A method for forming solder bumps on a circuit board, which is formed with a solder resist and pads thereon and said pads are exposed from said solder resist, said method comprising the steps of:
strengthening said solder resist;
roughing said solder resist;
laying over a photosensitive dry film onto said solder resist;
forming openings on said photosensitive dry film for exposing said pads and said openings being corresponded to said pads respectively;
forming solder bumps on said pads within said openings; and
removing said photosensitive dry film.

2. The method of claim 1, wherein said step of strengthening said solder resist includes irradiating said solder resist by ultraviolet rays.

3. The method of claim 1, wherein said step of roughing said solder resist includes applying plasma treatments to said solder resist.

4. The method of claim 1, wherein said step of forming openings on said photosensitive dry film includes exposing and developing said photosensitive dry film.

5. The method of claim 1, wherein said step of forming solder bumps on said pads within said openings includes:
filling said openings with solder; and
applying reflow treatments to said solder for forming spherical solder bumps on said pads.

6. The method of claim 2, wherein said step of roughing said solder resist includes applying plasma treatments to said solder resist.

7. The method of claim 6, wherein said step of forming openings on the photosensitive dry film includes exposing and developing said photosensitive dry film.

8. The method of claim 7, wherein said step of forming solder bumps on said pads within said openings includes:
filling said openings with solder; and
applying reflow treatments to said solder for forming spherical solder bumps on said pads.
